(19) United States
(12) Patent Application Publication
(10) Pub. No.: US 2014/0284779 A1
(43) Pub. Date: Sep. 25, 2014

(54) SEMICONDUCTOR DEVICE HAVING REINFORCED WIRE BONDS TO METAL TERMINALS

(71) Applicant: TEXAS INSTRUMENTS INCORPORATED, Dallas, TX (US)

(72) Inventors: KAZUNORI HAYATA, HAYAMI-GUN (JP); NOBORU NAKANISHI, HAYAMI-GUN (JP)

(73) Assignee: Texas Instruments Incorporated, Dallas, TX (US)

(21) Appl. No.: 13/847,561

(22) Filed: Mar. 20, 2013

(51) Int. Cl. H01L 23/00; H01L 23/495

(52) U.S. Cl. CPC H01L 24/43; H01L 23/49575; H01L 24/42
USPC 257/676; 438/123

(57) ABSTRACT

A method of assembling semiconductor devices includes connecting a bond wire between a bond pad on a top side surface of a semiconductor die having its bottom side surface attached to a package substrate and a bonded area within a metal terminal of the package substrate, where a bond is formed along a bonding interface between the bond wire and bonded area. After the connecting, a metal paste is applied including a plurality of metal particles and a binder over the bonded area. The metal paste is sintered to densify the plurality of metal particles to form reinforcement material including within a portion of the bonding interface for providing improved wirebond performance, such as increased pull strength.

### FIELD

Disclosed embodiments relate to leadframes for semiconductor devices, and more particularly to wire bonded semiconductor devices.

### BACKGROUND

In the manufacture of semiconductor integrated circuits (ICs), semiconductor IC die (or chips) are commonly mounted on a leadframe, followed by enclosing the IC die and part of the leadframe in a plastic casing to form an IC package. The IC package can be mounted on a printed circuit board (PCB) for interconnection of the electronic devices on the IC die with external circuitry. A leadframe should provide good bondability, molding compound characteristic, and solderability, so that it can facilitate the packaging process. To provide these characteristics, various coatings may be formed on the leadframe surface.

A conventional method for providing improved bondability for the interconnection between bond wires and bonding areas of a leadframe is to electroplate a metal such as silver (Ag) on the bonded areas including on the surface of the metal terminals within the package before wire bonding. Wire bonding is generally performed by a first bonding which forms a ball bond by placing a capillary over the bond pad of the IC die with a ball of the wire extending out of the capillary, and then a second bonding for bonding to the metal terminal. In the second bonding the capillary may be moved to a metal terminal (e.g., lead finger) of the leadframe to which a second bond is made with the wire travelling with respect to the capillary bore, and a stitch bond can be made to the metal terminal (e.g., lead finger) using the capillary with the wire then being broken, leaving a small wire pigtail extending out of the capillary.

Wire bonding can also be used to bond a semiconductor die to a variety of package substrates besides leadframes. For example, other package substrates can include multi-layer printed circuit boards (PCBs), thick film ceramics, glass substrates and flexible circuits.

There can be a problem with weak wire bond connections and resulting instability of the wire bonds to the metal terminals of the package substrate, which can cause electrical instabilities (resulting in high resistance contacts) and mechanical failures (e.g., low pull strength of the bond leading to pulling apart). Conventional solutions to this problem involve changing wire bonding process parameters and/or selecting different bond wire-metal terminal material combinations, including metal plated layers on the top surface of the metal terminals.

### SUMMARY

Disclosed embodiments recognize weak wire bond connections and resulting instability of the wire bond from bond pads on a semiconductor die to metal terminals on a package substrate which lead to electrical instabilities (resulting in high resistance contacts) and mechanical failures (e.g., low pull strength leading to pulling apart) can be due to a space between a portion of the bonding interface between the bond wires and the metal terminals. Disclosed embodiments solve this problem of weak wire bond connections by reinforcing the wire bond connection by applying a metal paste over the bonding area after wire bonding operations, then sintering the metal paste to form a metal reinforcement material. The reinforcement material strengthens the wire bond connection including by filling spaces present in the bonding interface between the bond wires and the metal terminals after wire bonding, such as spaces due to the scrub motion or ultrasonic forces during the bonding of the bond wires. The reinforcement material enables higher wire bond performance, including improved wire bond ability, pull strength, shear strength and break mode.

Regarding the method, after wirebonding, a metal paste that includes metal particles and a binder is applied, such as by an inkjet or other dispense apparatus. The applied metal paste can penetrate into the space of wire bonding and also cover the bond (e.g., stitch bond). The metal paste is then sintered to remove the binder and form the reinforcement material.

### BRIEF DESCRIPTION OF THE DRAWINGS

Reference will now be made to the accompanying drawings, which are not necessarily drawn to scale, wherein:

FIG. 1 is a flow chart that shows steps in an example method of assembling semiconductor devices including adding a reinforcement material to a bond after bonding a bond wire from a semiconductor die to a metal terminal, according to an example embodiment.

FIG. 2A is a cross sectional depiction of a partially assembled semiconductor device after connecting a bond wire between a bond pad on a top side surface of a semiconductor die having its bottom side surface attached to a die pad of a leadframe to a metal terminal of a leadframe.

FIG. 2B is a cross sectional depiction of a partially assembled semiconductor device after dispensing a metal paste including metal particles and a binder onto a bonded area of a plurality of metal terminals of the leadframe shown in FIG. 2A, according to an example embodiment.

FIG. 3A is cross-sectional view of an encapsulated semiconductor package having a leadframe including a disclosed reinforcement material within a portion of the bonding interface and over the bonded area over the bond wire on the metal terminals, according to an example embodiment.

FIG. 3B is a top view depiction of an example stitch bond having disclosed reinforcement material covering and lateral to the stitch bond.

FIGS. 4A-C show successive scanned depictions based on actual images enhanced in FIG. 4B and 4C that show a space at the bonding interface between a bond wire and a bonded area of the metal terminals after wire bonding (FIG. 4A), and the formation of disclosed reinforcement material (FIG. 4B and 4C) within a portion of the bonding interface between the bond wire and the bonded area, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

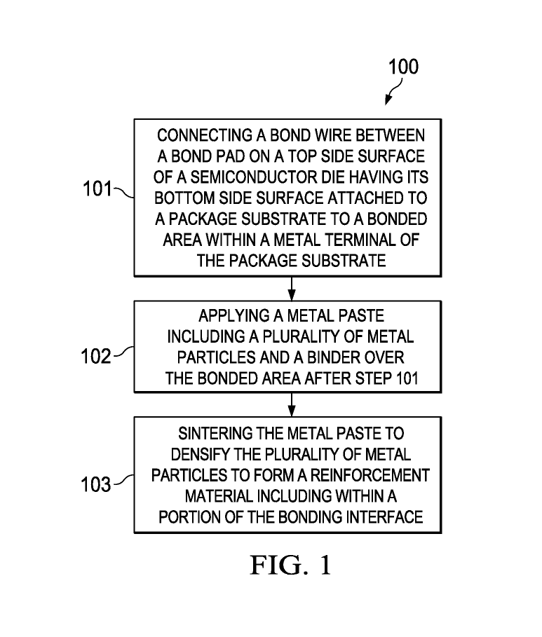

FIG. 1 is a flow chart that shows steps in an example method 100 of assembling semiconductor devices including forming a reinforcement material after bonding a bond wire by dispensing a metal paste over the bonded area of a metal terminal of a package substrate and then sintering the metal paste, according to an example embodiment. The reinforcement material is included within a portion of the bonding interface between the bond wire and the bonded area. Disclosed embodiments can be applied to wire bonding between semiconductor die and a variety of package substrates, including metallic frames to form leadless packages having internal terminals comprising lead fingers and leaded packages where the plurality of metal terminals comprise a plurality of leads (or pins) including an internal lead portion and an external lead portion. Disclosed embodiments can also be applied to provide wire bonds from semiconductor die to metal terminals (e.g., contact pads) on other package substrate including, for example, printed circuit boards (PCBs) such as multi-layer PCBs, thick film ceramics, glass substrates and flexible substrates.

Step 101 comprises connecting a bond wire between a bond pad on a top side surface of a semiconductor die having its bottom side surface attached to a package substrate to a bonded area within a metal terminal of the package substrate. In the case the package substrate is a leadframe, the leadframe generally includes a plurality of metal terminals. The top side surface of the semiconductor die is an active surface (e.g., silicon surface) which generally includes a plurality of interconnected devices that include transistors and other circuit elements configured together to provide a circuit function.

In the bonding process, a plurality bond wires, such as gold or aluminum wires, each having one end bonded to a bond pad on the semiconductor die and the other end bonded to the metal terminal are used for the interconnect. Known wire bonding techniques may be used. For example, a stitch bond may be formed along a bonding interface between the bond wire and the bonded area of the metal terminal under bond wire. The bondwire material may comprise a variety of materials, including Au, Cu, or Al. The base metal of the leadframe is generally copper or a copper alloy including Alloy 194, C7025, KCF125, EFTEC, or can be other than copper comprising such as a nickel/ferrite alloy (e.g., Ni—Fe 42 alloy). A typical thickness for the base metal is 0.15 mm to 0.30 mm. The metal terminals can be standard metal terminals (e.g., copper) or be plated metal terminals.

Step 102 comprises applying a metal paste including a plurality of metal particles, and a binder over the bonded area after the connecting/bonding step 101. As used herein, a binder is a material for dispersing the metal particles in the paste, and to enable printing of the metal particles. The binder is generally an organic binder. The binder can be a solvent-binder, or a separate solvent may be added. A computer controlled ink jet apparatus can be used for the applying. Other applying/dispensing apparatus can include computer controlled needle dispensers (air, mechanical) and jet dispensers. These methods all dispense metal particles in metal paste, and can print a paste with high resolution.

In the case of ink-jet printing, the ink-jet printing action can be induced by various technologies known in the art, including piezoelectric or thermal ink jet printers. Ink-jet printing operates via a series of nozzles to shoot small droplets of liquid onto a surface with high precision. The nozzles are part of a print head that can be moved back and forth (e.g., by a stepper motor) with respect to the surface being printed. The surface being printed can also be moved relative to the print head.

The applying provides a paste thickness that can be in a range in thickness after sintering (step 103) of at least 1 μm, typically providing a thickness range between 2 μm and 8 μms. The metal particles in the metal paste can comprise metals particles, such nanoparticles comprising silver, copper, aluminum or gold, or alloys thereof.

Step 103 comprises sintering the metal paste to densify the plurality of metal particles to form a reinforcement material including within a portion of the bonding interface. As known in the art, sintering includes removing the binder and optional solvent if present, such as by heat and/or ultraviolet light.

An example sintering process includes a temperature generally≧100° C., optionally under pressure (e.g., 2 to 10 atmospheres), in a non-oxidizing atmosphere. A reducing gas atmosphere can be used to remove surface metal oxide for metals such as copper and to prevent oxidation. The reducing gas as used herein is a gas or gas mixture capable of generating H* radicals or H+ ions through decomposition or dissociation. The reducing gas can include one or more of hydrazine (N₂H₄) derivatives, NH₃, H₂, SiH₄ and Si₂H₆. In one particular embodiment, the reducing gas is a gas mixture, such as forming gas (N₂+H₂) which is a mixture of H₂ and N₂ where the respective mole fractions can vary.

In the case the package substrate comprises a leadframe, step 104 comprises encapsulating the semiconductor device in an encapsulating material, such as a polymer. An electrically non-conducting (dielectric) encapsulation polymer can be molded over the package in the encapsulation step. The packaged semiconductor device is then generally electrically tested.

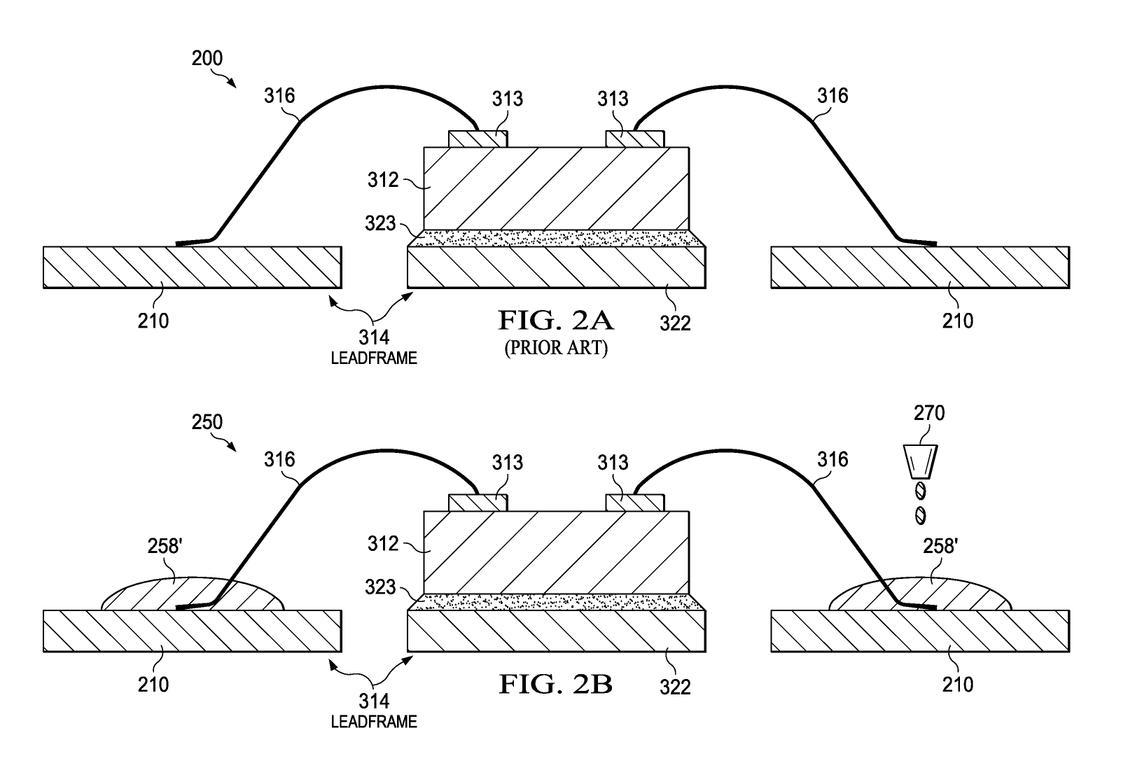

FIG. 2A is a cross sectional depiction of a partially assembled semiconductor device 200 after connecting a bond wire 316 between a bond pad 313 on a top side surface of a semiconductor die 312 having its bottom side surface attached by a die attach material 323 to a die pad 322 of a leadframe to a metal terminal (e.g., lead finger) 210 of the leadframe 314. FIG. 2B is a cross sectional depiction of a partially assembled semiconductor device 250 while inkjet dispensing of a metal paste 258′ including metal particles in a binder and optional solvent onto a bonding area of the metal terminals 210 shown in FIG. 2A, according to an example embodiment. An inkjet 270 is shown dispensing the metal paste. The metal paste being somewhat fluid can penetrate into the space of wire bonding (along the bonding interface between the bond wire 316 and surface of the metal terminal 210) and also cover the bond (e.g., a stitch bond). Upon sintering of the metal paste as described above, the metal paste becomes an electrically conductive metal reinforcement material. This reinforcement material strengthens the wire bond connection, such as adding to the pull strength of the wire bond.

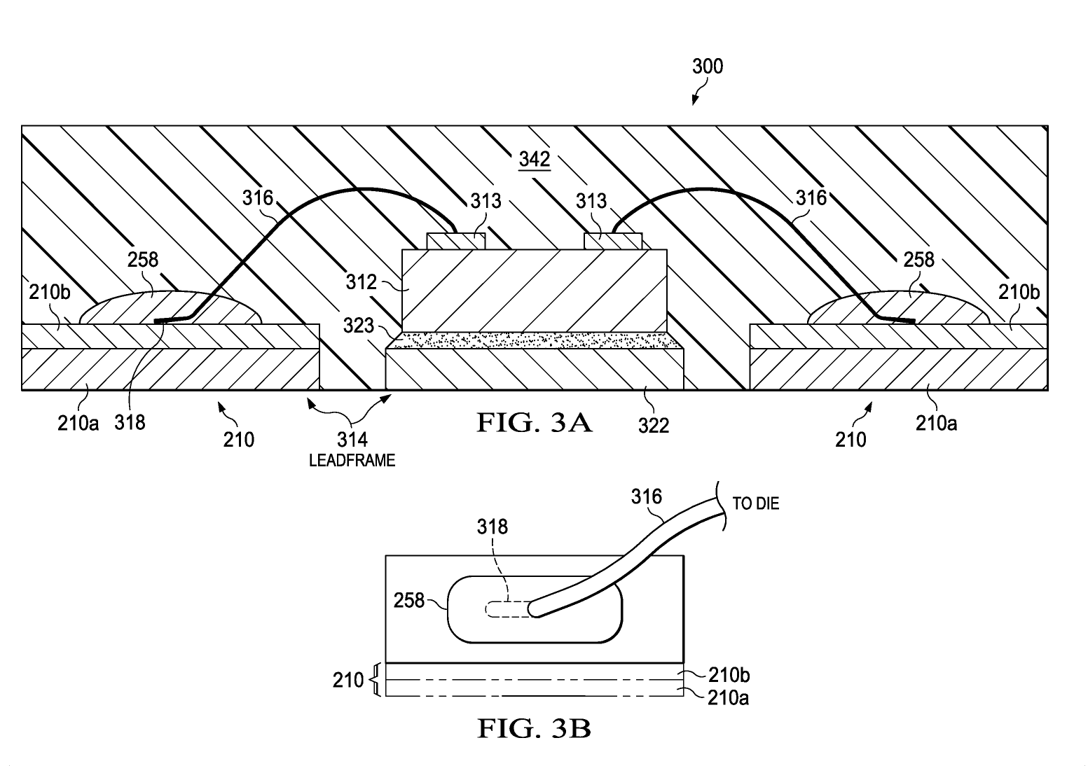

FIG. 3A is cross-sectional view of an encapsulated semiconductor package 300 having a leadframe including a disclosed reinforcement material 258 within a portion of the bonding interface and over the bonded area over the bond wire 316 on the metal terminals 210, according to an example embodiment. Metal terminals 210 comprise leads for a leaded packages and lead fingers for a leadless package (e.g., dual-flat no-leads (DFN)). The semiconductor die 312 is attached to the die pad 322 of the leadframe 314 by die attach material 323. Metal terminals 210 are shown in including a base metal portion 210a and an optional plated metal portion 210b thereon. Stitch bonds are shown as 318 which define the bonded area of the plated metal portion 210b of metal terminals 210. An electrically non-conducting (dielectric) encapsulation polymer 342 is molded over the package 300.

FIG. 3B is a top view depiction of an example stitch bond 318 having disclosed reinforcement material 258 covering and lateral to the stitch bond. This depiction illustrates that the reinforcement material 258 can cover the end of the bond wire 316 at the bond 318, and filling the interface space between the bond wire 316 and the plated metal portion 210b of the metal terminal 210 at the bond 318. The reinforcement material 258 being over and lateral to the bonds 318 can add additional strength to the bond beyond the bond having disclosed filling of the interface space between the bond wire 316 at the bond 318.

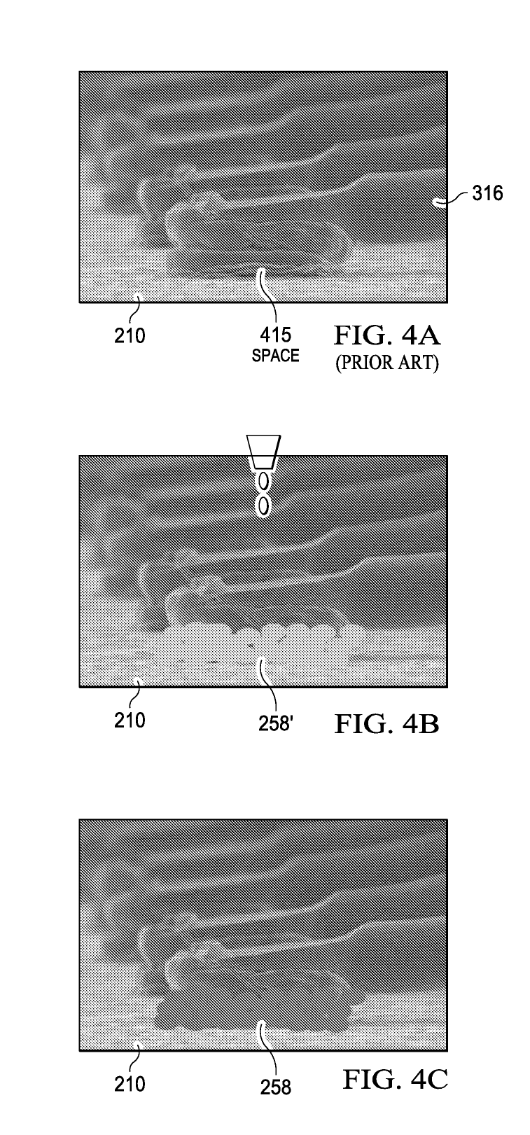

FIGS. 4A-C show successive depictions based on images enhanced in FIG. 4B and 4C to show the formation of a disclosed reinforcement material within a portion of the bonding interface between the bond wire and the bonded area, according to an example embodiment. FIG. 4A depicts a space 415 along the bonding interface (under the stitch bond shown) between the bond wire 316 and the surface of the metal terminal 210. The space 415 may be made by a scrubbing motion, or ultrasonic energy during the bonding of the bond wire 316 to the surface of the metal terminal 210.

FIG. 4B depicts the space 415 being filled by an inkjet 270 applying a metal paste 258′. FIG. 4C is a depiction after sintering the metal paste 258′ (removing the binder) to form the reinforcement material 258 which fills the former space 415. Although the reinforcement material 258 is not shown over the bond wire 316 over the metal terminal 210, the reinforcement material 258 can also be on the bond wire 316 over the metal terminal 210, such as covering the bond wire 316 over the metal terminal 210 as shown in FIG. 3A (not just filling the space 415).

Disclosed embodiments can be integrated into a variety of assembly flows to form a variety of different semiconductor IC devices and related products. The assembly can comprise single semiconductor die or multiple semiconductor die, such as PoP configurations comprising a plurality of stacked semiconductor die. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A method of assembling semiconductor devices, comprising:
connecting a bond wire between a bond pad on a top side surface of a semiconductor die having its bottom side surface attached to a package substrate and a bonded area within a metal terminal of said package substrate, wherein a bond is formed along a bonding interface between said bond wire and said bonded area;
after said connecting, applying a metal paste including a plurality of metal particles and a binder over said bonded area, and sintering said metal paste to densify said plurality of metal particles to form a reinforcement material including within a portion of said bonding interface.

2. The method of claim 1, wherein said metal terminal includes a base metal having a plated metal layer thereon.

3. The method of claim 1, wherein said applying comprises inkjet dispensing.

4. The method of claim 1, wherein said metal terminal includes a top surface having a first composition, and wherein said reinforcement material comprises a second composition different from said first composition.

5. The method of claim 1, wherein said reinforcement material comprises particles comprising silver, copper, aluminum or gold, or alloys thereof.

6. The method of claim 1, wherein a thickness of said reinforcement material is from 2 μm to 8 μm.

7. The method of claim 1, wherein said bond comprises a stitch bond.

8. The method of claim 1, wherein said package substrate comprises a leadframe, wherein said bottom side surface is attached to a die pad of said leadframe, and wherein said metal terminal is outside said die pad.

9. The method of claim 1, wherein said reinforcement material extends over and lateral to said bond wire in said bonded area.

10. A semiconductor device assembly, comprising:
a package substrate on which a semiconductor die including a top side surface having a plurality of bond pads thereon is attached;
a plurality of metal terminals including a surface having a first composition,
bond wires connecting between said plurality of bond pads and a bonded area within said plurality of metal terminals, wherein a bond is provided along a bonding interface between said bond wires and said bonded area, and
a reinforcement material including within a portion of said bonding interface, wherein said reinforcement material comprises a second composition different from said first composition.

11. The semiconductor device assembly of claim 10, wherein said reinforcement material extends over and lateral to said bond wires in said bonded area.

12. The semiconductor device assembly of claim 10, wherein said first composition comprises particles comprising silver, copper, aluminum or gold, or alloys thereof.

13. The semiconductor device assembly of claim 10, wherein a thickness of said reinforcement material averages 2 μm to 8 μm.

14. The semiconductor device assembly of claim 10, wherein said bond comprises a stitch bond.

15. The semiconductor device assembly of claim 10, wherein said package substrate comprises a leadframe, wherein a bottom side surface of said semiconductor die is attached to a die pad of said leadframe, and said plurality of metal terminals is outside said die pad.

16. A semiconductor device assembly, comprising:
a die pad on which a semiconductor die including a top side surface having a plurality of bond pads thereon is attached;
a plurality of metal terminals outside said die pad including a surface having a first composition,
bond wires connecting between said plurality of bond pads and a bonded area within said plurality of metal terminals, wherein a bond is provided along a bonding interface between said bond wires and said bonded area, and
a reinforcement material including within a portion of said bonding interface, wherein said reinforcement material comprises a second composition different from said first composition.
